(19) United States
(12) Patent Application Publication
(10) Pub. No.: US 2015/0357498 A1
(43) Pub. Date: Dec. 10, 2015

(54) VOLTAGE SOURCE GENERATOR AND VOLTAGE SOURCE MODULE

(71) Applicant: MH SOLAR COMPANY LIMITED, Kaohsiung City (TW)

(72) Inventors: MEI-HUAN YANG, KAOHSIUNG CITY (TW); CHIUN-YEN TUNG, KAOHSIUNG CITY (TW); TERRY ZAHURANEC, NORTH OLSMSTED, OH (US); CHENG-LIANG WU, KAOHSIUNG CITY (TW); CHIN-WEI HSU, KAOHSIUNG CITY (TW); WEI-SHENG CHAO, KAOHSIUNG CITY (TW); KUN-SAIN CHEN, KAOHSIUNG CITY (TW); YING-JIE PENG, KAOHSIUNG CITY (TW); YING-LIN TSENG, KAOHSIUNG CITY (TW); MING-ZEN CHUANG, KAOHSIUNG CITY (TW); PING-PANG LEE, KAOHSIUNG CITY (TW)

(21) Appl. No.: 14/296,195

(22) Filed: Jun. 4, 2014

(51) Int. Cl. H01L 31/054; H02S 40/22; H01L 31/048

(52) U.S. Cl. CPC H01L 31/0547; H01L 31/048; H02S 40/22

(57) ABSTRACT

A voltage source generator includes a light-transmissive component and a plurality of vertical multi junction (VMJ) cells. The light-transmissive component includes an inner space. The VMJ cells are disposed within the inner space of the light-transmissive component to receive light and perform light-to-electricity conversion. The VMJ cells are connected in series. The voltage source generator can generate a kV-level voltage and meet small-sized and low-cost demands. A voltage source module includes at least two voltage source generators connected to at least one electrical connector.

### FIELD

The disclosure relates to a voltage source generator, more particular to a voltage source generator with vertical multi-junction (VMJ) cells.

### BACKGROUND

High voltage electrostatic fields (HVEF) have found a wide range of applications in different areas such as plant growth regulation, food sterilization, and disease prevention. The HVEF system generally works at kilovolts (kV) levels, which are voltage levels that are not available from small- or medium-sized conventional energy sources. Therefore, the HVEF system needs a power source that can supply kilovolts to generate the electrostatic fields that are needed for these applications. However, the use of the conventional kV-level power sources causes the production cost of the HVEF system to become high.

Vertical multi-junction (VMJ) cell is a solar cell device which has a small feature size and allows output voltages higher than conventional single junction cells. Typically a 1 cm×1 cm VMJ cell can generate a voltage of no less than 25 volts under one sun illumination whereas conventional single junction cells can only generate a few volts at best. Nevertheless, generating a kV-level voltage is still challenging to modern VMJ cells lacking high-efficiency optical designs.

In view of the foregoing, it is greatly desired to develop a voltage source generator using VMJ cells which may generate a kV-level voltage and meet small-sized and low-cost demands.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates an exploded perspective view of a voltage source generator in accordance with some embodiments of the present disclosure.

FIG. 2 illustrates a perspective view of a voltage source generator in accordance with some embodiments of the present disclosure.

FIG. 3 illustrates a cross-sectional view along line A-A of FIG. 2.

FIG. 4 illustrates a cross-sectional view along line B-B of FIG. 2.

FIG. 5 illustrates an index-matching material idirecting light onto VMJ cells in accordance with some embodiments of the present disclosure.

FIG. 6 illustrates a light reflector in directing light on VMJ cells in accordance with some embodiments of the present disclosure.

FIG. 7 illustrates a cross-sectional view of a conducting component in accordance with some embodiments of the present disclosure.

FIG. 8 illustrates a perspective view of a voltage source generator in accordance with some embodiments of the present disclosure.

FIG. 9 illustrates a cross-sectional view of a voltage source generator with an artificial light source in accordance with some embodiments of the present disclosure.

FIG. 10a illustrates a side view of a VMJ cell in accordance with some embodiments of the present disclosure.

FIG. 10b illustrates a partial enlarged view of a VMJ cell in accordance with some embodiments of the present disclosure.

FIG. 11 illustrates a perspective view of a VMJ cell in accordance with some embodiments of the present disclosure.

FIG. 12 illustrates a side view of a VMJ cell in accordance with some embodiments of the present disclosure.

FIG. 13 illustrates a side view of a VMJ cell in accordance with some embodiments of the present disclosure.

FIG. 14 illustrates a side view of a VMJ cell in accordance with some embodiments of the present disclosure.

FIG. 15 illustrates a perspective view of a voltage source module in accordance with some embodiments of the present disclosure.

FIG. 16 illustrates an exploded perspective view of a voltage source generator in accordance with some embodiments of the present disclosure.

FIG. 17 illustrates a cross-sectional view along line C-C of FIG. 13.

FIG. 18 illustrates a light reflector directing light onto VMJ cells in accordance with some embodiments of the present disclosure.

### DETAILED DESCRIPTION OF THE INVENTION

It is to be understood that the following disclosure provides many different embodiments or examples, for implementing different features of various embodiments. Specific examples of components and arrangements are described below to simplify the present disclosure. The present disclosure may, however, be embodied in many different forms and should not be construed as being limited to the embodiments set forth herein; rather, these embodiments are provided so that this description will be thorough and complete, and will fully convey the present disclosure to those of ordinary skill in the art. It will be apparent, however, that one or more embodiments may be practiced without these specific details.

In addition, the present disclosure may repeat reference numerals and/or letters in the various examples. This repetition is for the purpose of simplicity and clarity and does not in itself dictate a relationship between the various embodiments and/or configurations discussed.

It will be understood that when an element is referred to as being “on” another element, it can be directly on the other element or intervening elements may be present. In contrast, when an element is referred to as being “directly on” another element, there are no intervening elements present.

It will be understood that singular forms “a”, “an” and “the” are intended to include the plural forms as well, unless the context clearly indicates otherwise.

Unless otherwise defined, all terms (including technical and scientific terms) used herein have the same meaning as commonly understood by one of ordinary skill in the art to which this invention belongs. It will be further understood that terms; such as those defined in commonly used dictionaries, should be interpreted as having a meaning that is consistent with their meaning in the context of the relevant art and the present disclosure, and will not be interpreted in an idealized or overly formal sense unless expressly so defined herein.

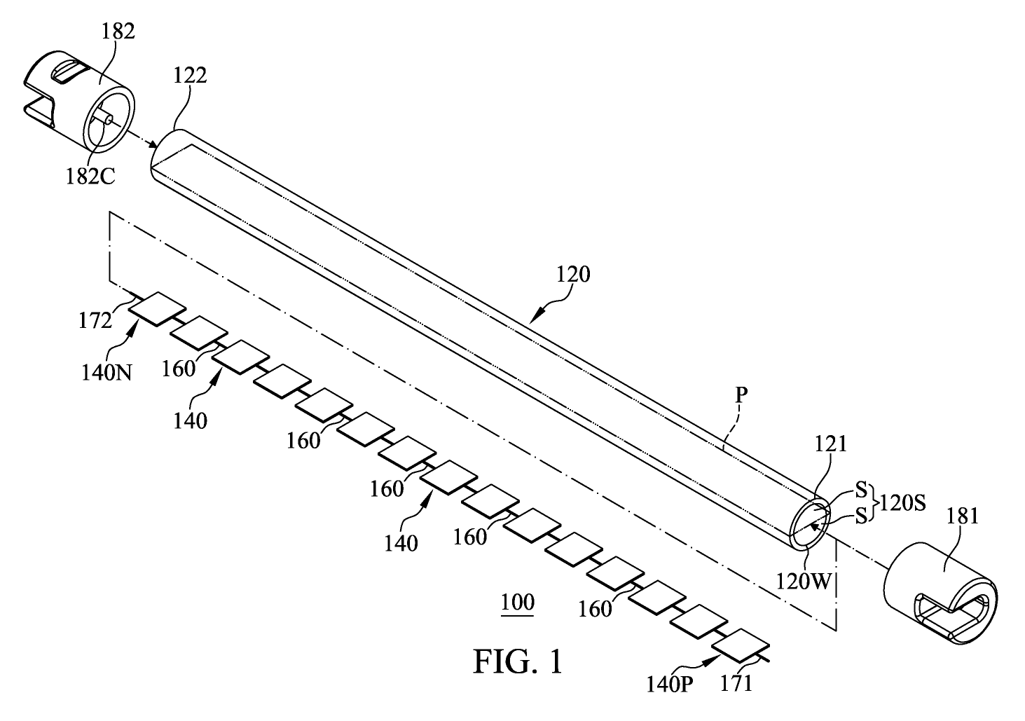

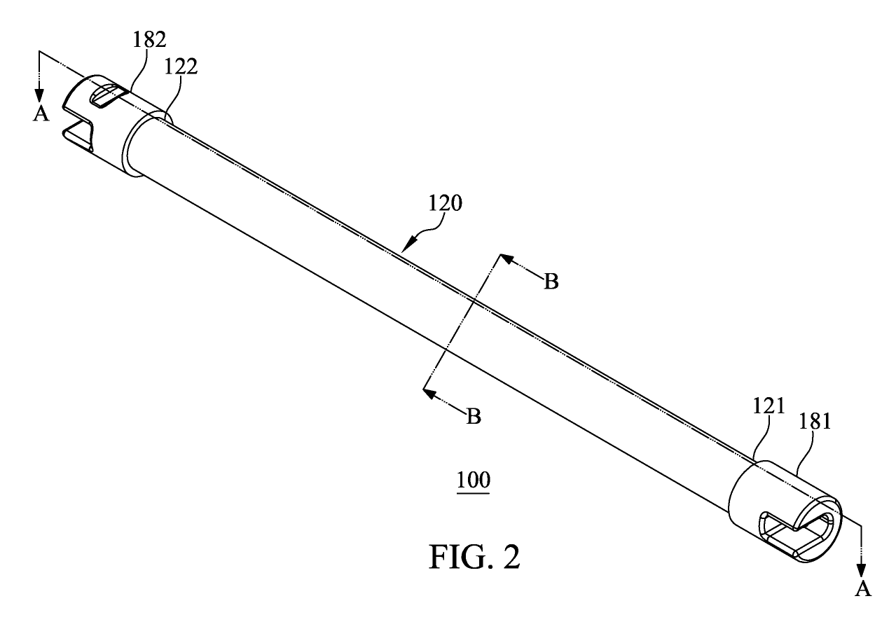

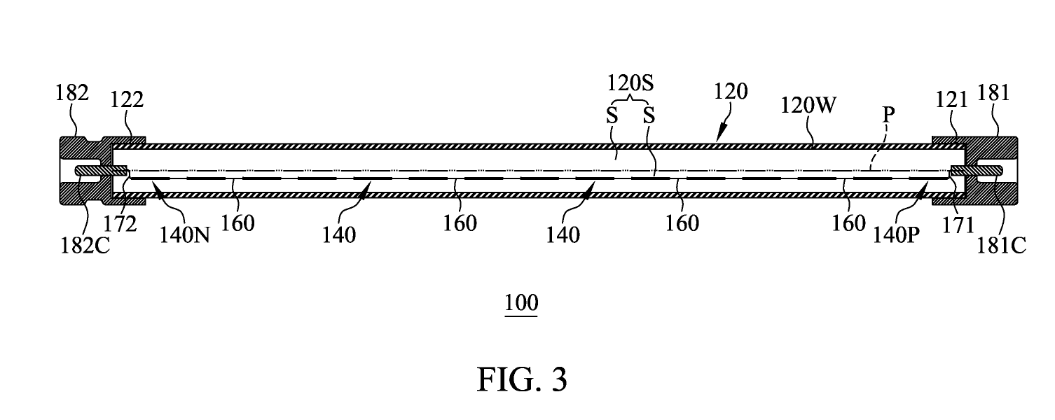

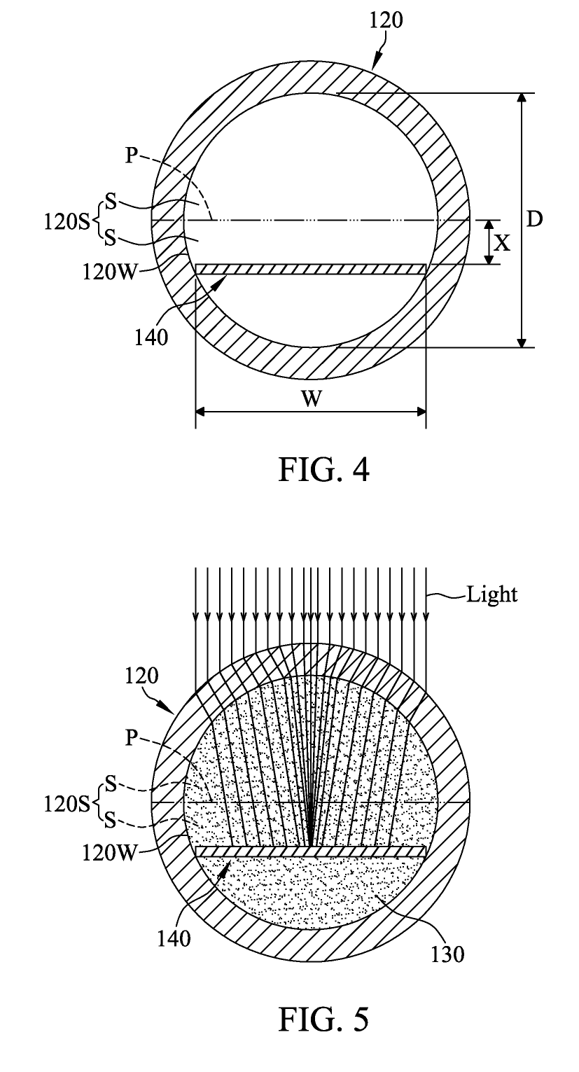

FIG. 1 illustrates an exploded perspective view of a voltage source is generator in accordance with some embodiments of the present disclosure. FIG. 2 illustrates a perspective view of a voltage source generator in accordance with some embodiments of the present disclosure. FIG. 3 illustrates a cross-sectional view along line A-A of FIG. 2. FIG. 4 illustrates a cross-sectional view along line B-B of FIG. 2.

Referring to FIGS. 1, 2, 3, and 4, a voltage source generator 100 is designed to generate a kV-level voltage. The voltage source generator 100 includes a light-transmissive component 120 and a plurality of vertical multi junction (VMJ) cells 140. In this embodiment, the light-transmissive component 120 is a light-transmissive tube.

The light-transmissive component 120 includes an inner space 120S, an inner wall 120W, a first end portion 121, and a second end portion 122. The second end portion 122 is opposite to the first end portion 121. The light-transmissive component 120 also has an internal diameter D and defines a bisecting plane P for dividing the inner space 120S into two spaces S. In some embodiments, the light-transmissive component 120 is made of glass. In some embodiments, the light-transmissive component 120 is made of plastic. In some embodiments, the light-transmissive component 120 can have different cross sectional shapes such as square, round, “D” shaped and other shapes that may serve the same purpose.

The VMJ cells 140 are disposed within the inner space 120S of the light-transmissive component 120 to receive light and perform light-to-electricity conversion. Furthermore, the VMJ cells 140 are located at one of the two spaces S and are in contact with the inner wall 120W. In some embodiments, the VMJ cells 140 are substantially parallel to the bisecting plane P and there is a distance X between each VMJ cell 140 and the bisecting plane P.

To generate the kV-level voltage, the VMJ cells 140 are connected in series. Furthermore, an increase in power conversion efficiency will increase the VMJ cell voltage output. In practice, increasing the light intensity on the VMJ cells 140 can enhance the light-harvesting efficiency, thereby improving the power conversion efficiency. Therefore, directing light on the VMJ cells 140 becomes very important.

FIG. 5 illustrates an index-matching material directing light onto VMJ is cells in accordance with some embodiments of the present disclosure.

Referring to 5, the inner space 120S of the light-transmissive component 120 is filled with an index-matching material 130. The index-matching material 130 can focus light that penetrates the light-transmissive component 120 on the VMJ cells 140 to enhance the light-harvesting efficiency. In some embodiments, the index-matching material 130 has a refractive index between about 1.0 and about 2.0.

In some embodiments, the index-matching material 130 may be selected from the group consisting of silica gel and epoxy resin. Furthermore, the VMJ cells 140 are encapsulated by the index-matching material 130.

In some embodiments, the index-matching material 130 can be an insulating material to prevent unwanted short circuits.

In addition to use the index-matching material 130, the feature sizes and the optical positions of the VMJ cells 140 also must be controlled to obtain the enhanced light-harvesting efficiency. Referring to FIG. 4, in some embodiments, each VMJ cell 140 has a width W smaller than the internal diameter D of the light-transmissive component 120. Also, a ratio of the distance X to the internal diameter D of the light-transmissive component 120 is between about 0.15 and about 0.45.

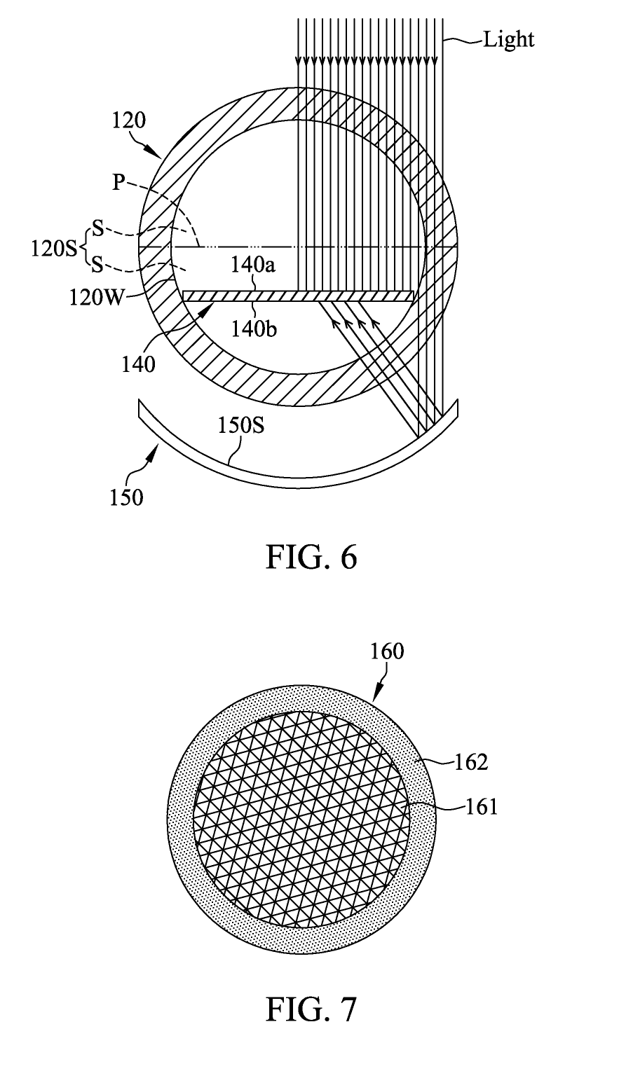

FIG. 6 illustrates a light reflector in directing light on VMJ cells in accordance with some embodiments of the present disclosure.

Referring to FIG. 6, some light is received by the VMJ cells 140. Some light exits the light-transmissive component 120. Hence, the light exiting the light-transmissive component 120 was wasted. To obtain a high light-harvesting efficiency, a light reflector 150 is disposed outside the light-transmissive component 120 for directing the light on the VMJ cells 140.

In some embodiments, each VMJ cell 140 includes a first light receiving surface 140a and a second light receiving surface 140b. The second light receiving surface 140b is opposite to the first light receiving surface 140a and faces the light reflector 150. Therefore, the light reflector 150 can direct the light exiting the light-transmissive component 120 toward the second light receiving surfaces 140b of is the VMJ cells 140.

To collect the light exiting the light-transmissive component 120, the light reflector 150 can include at least one concave surface 150S. The at least one concave surface 150S is corresponding to the second light receiving surfaces 140b of the VMJ cells 140. In some embodiments, the light reflector 150 can be a plate reflector. In some embodiments, the light reflector 150 can be made up of angled flat or curved sections.

FIG. 7 illustrates a cross-sectional view of a conducting component in accordance with some embodiments of the present disclosure.

Referring to FIGS. 1, 3, and 7, the voltage source generator 100 further includes a plurality of conducting components 160. Each conducting component 160 is disposed between and connected to two adjacent VMJ cells 140. In some embodiments, the VMJ cells 140 are connected in series through the conducting components 160.

In some embodiments, each conducting component 160 includes a metal wire 161 and a polyvinylidene fluoride (PVDF) coating 162. The metal wire 161 is encapsulated with the PVDF coating 162, leading to electrical insulation, thereby preventing unwanted short circuits. In some embodiments, the metal wire 161 may be made of one selected from the group consisting of copper, nickel, tungsten, and molybdenum.

In addition to the conducting components 160, a positive output component 171 and a negative output component 172 are provided to output the kV level voltage of the voltage source generator 100. In some embodiments, the VMJ cells 140 include a positive output VMJ cell 140P and a negative output VMJ cell 140N. The positive output component 171 is connected to the positive output VMJ cell 140P, and the negative output component 172 is connected to the negative output VMJ cell 140N. In some embodiments, the positive and negative output components 171, 172 are made of the same material as the conducting components 160.

To seal the light-transmissive component 120, a first end cap 181 and a second end cap 182 are provided. The first end cap 181 is disposed at the first end is portion 121, and the second end cap 182 is disposed at the second end portion 122. In some embodiments, the positive output component 171 can be connected to the first end cap 181, and the negative output component 172 can be connected to the second end cap 182. Furthermore, the inner space 120S of the light-transmissive component 120 can be a vacuum space. In some embodiments, the inner space 120S of the light-transmissive component 120 can be filled with a gas. In some embodiments, the gas can be argon or other inert gas.

In some embodiments, the first end cap 181 can include an electrical contact 181 C connected to the positive output component 171. The second end cap 182 can also include an electrical contact 182C connected to the negative output component 172.

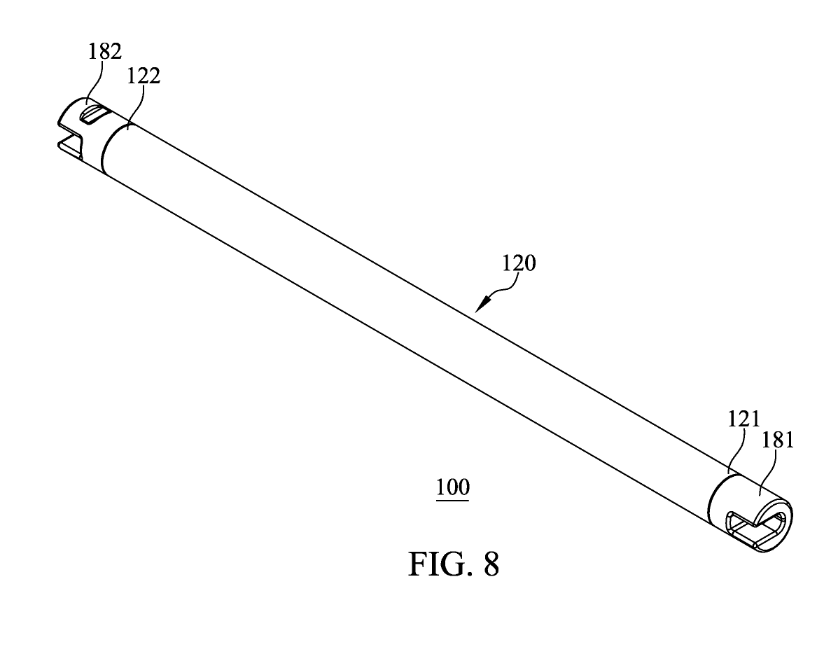

FIG. 8 illustrates a perspective view of a voltage source generator in accordance with some embodiments of the present disclosure.

Referring to FIG. 8, in some embodiments, the first and/or second end caps 181, 182 can be flush to an outside surface of the light-transmissive component 120 and slide into the light-transmissive component 120.

It should be noted that although sunlight is referred to as the illuminating source, other light sources such as LED's, incandescent, or other manmade sources can be used as primary or backup illumination sources.

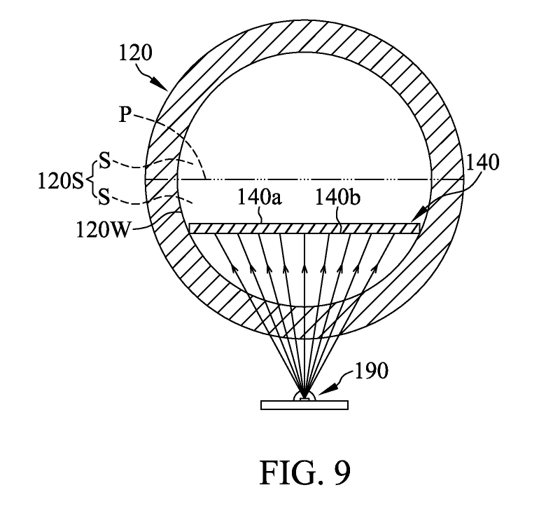

FIG. 9 illustrates a cross-sectional view of a voltage source generator with an artificial light source in accordance with some embodiments of the present disclosure.

Referring to FIG. 9, an artificial light source 190 is provided to enhance or replace the natural light intensity on the VMJ sells 140, thereby enhancing the output voltage of the voltage source generator 100. The artificial light source 190 is disposed outside the light-transmissive component 120 and illuminates the VMJ cells 140. In some embodiments, the artificial light source 190 may be disposed within the light-transmissive component 120. In some embodiments, the artificial light source 190 may be selected from the group consisting of LED, incandescent lamp, fluorescent lamp, xenon arc, tungsten halogen, high intensity discharge lamps and is combinations.

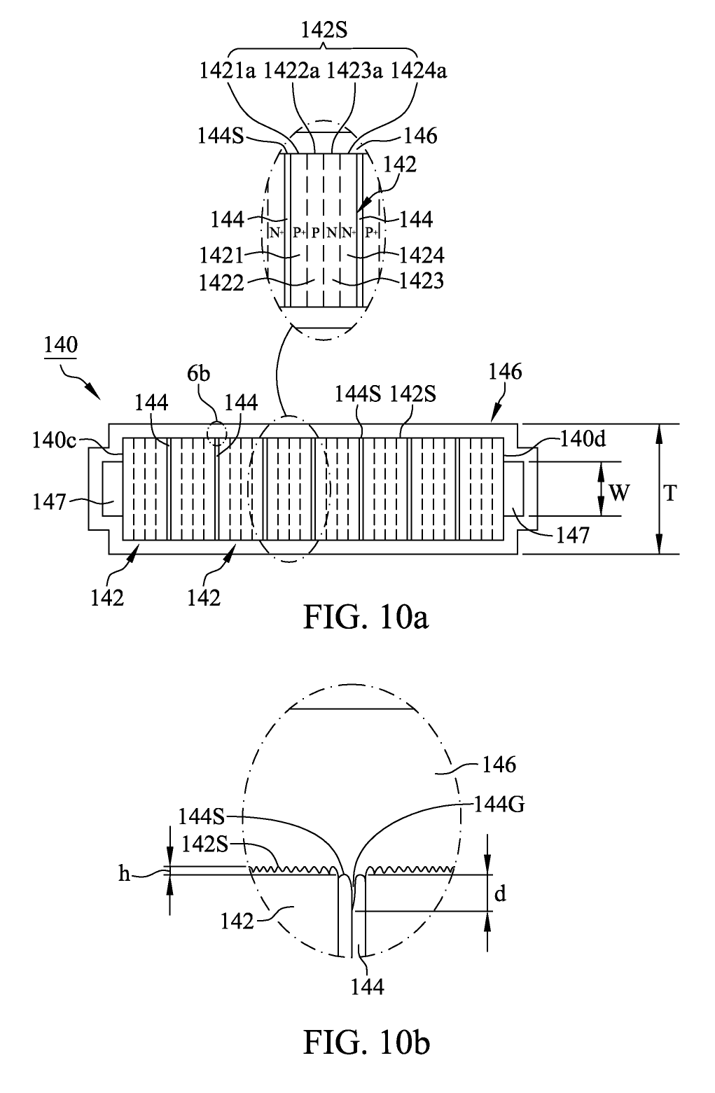

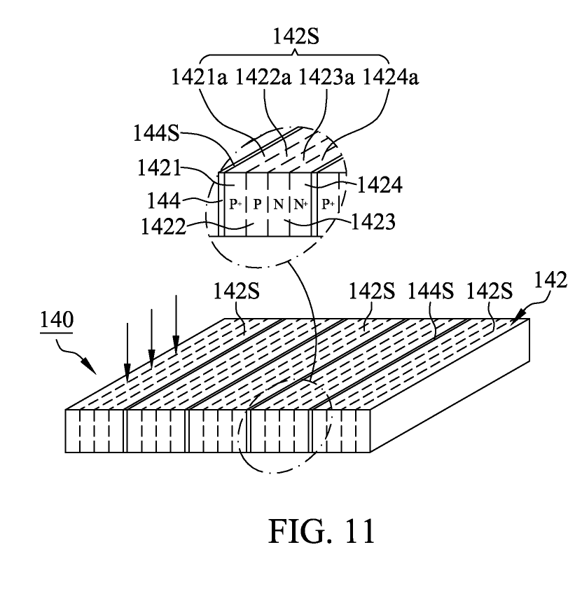

FIG. 10a illustrates a side view of a VMJ cell in accordance with some embodiments of the present disclosure. FIG. 10b illustrates a partial enlarged view of a vertical multi-junction (VMJ) cell in accordance with some embodiments of the present disclosure. FIG. 11 illustrates a perspective view of a VMJ cell in accordance with some embodiments of the present disclosure.

Referring to FIGS. 10a, 10b, and 11, in some embodiments, each VMJ cell 140 includes a plurality of PN junction substrates 142 and a plurality of electrode layers 144. The PN junction substrates 142 are spaced from each other. The PN junction substrates 142 are made of silicon (Si), and the silicon purity is between about 4N and about 11N. In some embodiments, the PN junction substrates 142 may be made of one selected from the group consisting of GaAs, Ge, InGaP, and their compositions. Each of the electrode layers 144 is disposed between and connected to two adjacent PN junction substrates 142, which can provide ohmic contacts with low resistance, high strength bonding, and well thermal conduction. In some embodiments, the electrode layers 144 are made of one selected from the group consisting of Si, Ti, Co, W, Hf, Ta, Mo, Cr, Ag, Cu, Al, and their alloy mixtures.

In order to improve carrier injections and ohmic contacts of the VMJ cell 140, each of the PN junction substrates 142 includes a light receiving surface 142S, a P+ type diffuse doping layer 1421, a P type diffuse doping layer 1422, an N type diffuse doping layer 1423 and an N+ type diffuse doping layer 1424. The P type s diffuse doping layer 1422 is connected to the P+ type diffuse doping layer 1421; the N type diffuse doping layer 1423 is connected to the P type diffuse doping layer 1422; and the N+ type diffuse doping layer 1424 is connected to the N type diffuse doping layer 1423. The P+ type diffuse doping layer 1421 and the N+ type diffuse doping layer 1424 of one PN junction substrate 142 are connected to different electrode layers 144.

The P+ type diffuse doping layer 1421 has a P+ type end surface 1421a. In some embodiments, a doping concentration of the P+ type diffuse doping layer 1421 is between about 10¹⁹ atom/cm³ and about 10²¹ atom/cm³. In some embodiments, a thickness of the P+ type diffuse doping layer 1421 is between about 0.3 μm and is about 3 μm.

The P type diffuse doping layer 1422 has a P type end surface 1422a. In some embodiments, a doping concentration of the P type diffuse doping layer 1422 is between about 10¹⁶ atom/cm³ and about 10²⁰ atom/cm³. In some embodiments, a thickness of the P type diffuse doping layer 1422 is between about 1 μm and about 50 μm.

The N type diffuse doping layer 1423 has an N type end surface 1423a. In some embodiments, a doping concentration of the N type diffuse doping layer 1423 is between about 10¹⁶ atom/cm³ and about 10²⁰ atom/cm³. In some embodiments, a thickness of the N type diffuse doping layer 1423 is between about 1 μm and about 50 μm.

The N+ type diffuse doping layer 1424 has an N+ type end surface 1424a. In some embodiments, a doping concentration of the N+ type diffuse doping layer 1424 is between about 10¹⁹ atom/cm³ and about 10²¹ atom/cm³. In some embodiments, a thickness of the N+ type diffuse doping layer 1424 is between about 0.3 μm and about 3 μm.

In some embodiments, the light receiving surface 142S includes the P+type end surface 1421a of the P+ type diffuse doping layer 1424, the P type end surface 1422a of the P type diffuse doping layer 1422, the N type end surface 1423a of the N type diffuse doping layer 1423 and the N+ type end surface 1424a of the N+ s type diffuse doping layer 1424. In some embodiments, the light receiving surface 142S is an uneven surface.

Each of the electrode layers 144 has an exposing surface 144S. To prevent the electrode layers 144 from being damaged in the process, there is a height difference h between the exposing surface 144S of each of the electrode layers 144 and the light receiving surface 142S of each of the PN junction substrates 142. In some embodiments, a position of the exposing surface 144S is lower than that of the light receiving surface 142S.

In order to reduce the carrier recombination probability, a passivation layer 146 is provided to cover the P+ type end surfaces 1421a of the P+ type diffuse is doping layers 1421, the P type end surfaces 1422a of the P type diffuse doping layers 1422, the N type end surfaces 1423a of the N type diffuse doping layers 1423, the N+type end surfaces 1424a of the N+ type diffuse doping layers 1424 and the exposing surfaces 144S of the electrode layers 144. The passivation layer 146 is formed by an atomic layer deposition (ALD) process. Furthermore, the passivation layer 146 is penetrable to light and is made of one selected from the group consisting of Al₂O₃, HfO₂, La₂O₃, SiO₂, TiO₂, ZnO, ZrO₂, Ta₂O₅, In₂O₃, SnO₂, ITO, Fe₂O₃, Nb₂O₅, MgO, Er₂O₃, WN, Hf₃N₄, Zr₃N₄, AlN, and TiN.

In addition to reduce the carrier recombination probability, the passivation layer 146 also can be used to mend surface defects and dangling bonds of the PN junction substrates 142, thereby reducing light induced degradation and enhancing the photovoltaic conversion efficiency. In some embodiments, a thickness of the passivation layer 146 is between about 10 nm and about 180 nm.

To improve a bonding strength between the passivation layer 146 and the electrode layers 144, each of the electrode layers 144 also includes a groove 144G recessed from the exposing surface 144S, and the grooves 144G of the electrode layers 144 are filled with the passivation layer 146. In some embodiments, a depth d of the groove 144G is greater than the height difference h.

The VMJ cell 140 also includes a first end surface 140c, a second end surface 140d and at least two conducting electrodes 147. The second end surface 140d s is opposite to the first end surface 140c. The conducting electrodes 147 are separately disposed on the first and second end surfaces 140c, 140d. The conducting electrodes 147 are used to output electric energy generated from the VMJ cell 140. In some embodiments, the conducting electrodes 147, the first end surface 140c and the second end surface 140d are covered with the passivation layer 146 to reduce the carrier recombination probability. In some embodiments, a width W of each of the conducting electrodes 147 is smaller than a thickness T of the VMJ cell 140.

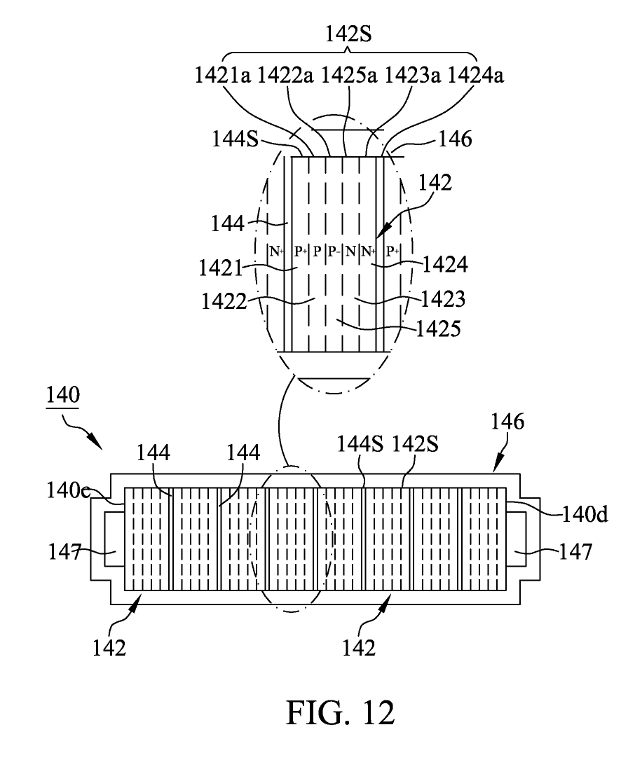

FIG. 12 illustrates a side view of a VMJ cell in accordance with some embodiments of the present disclosure.

Referring to FIG. 12, each of the PN junction substrates 142 can further is include a P− type diffuse doping layer 1425. The P− type diffuse doping layer 1425 is disposed between and connected to the P type diffuse doping layer 1422 and the N type diffuse doping layer 1423. The P− type diffuse doping layer 1425 has a P− type end surface 1425a, and the P− type end surface 1425a is also covered with the passivation layer 146 to reduce the carrier recombination probability. In some embodiments, a doping concentration of the P− type diffuse doping layer 1425 is between about 10¹⁴ atom/cm³ and about 10¹⁸ atom/cm³.

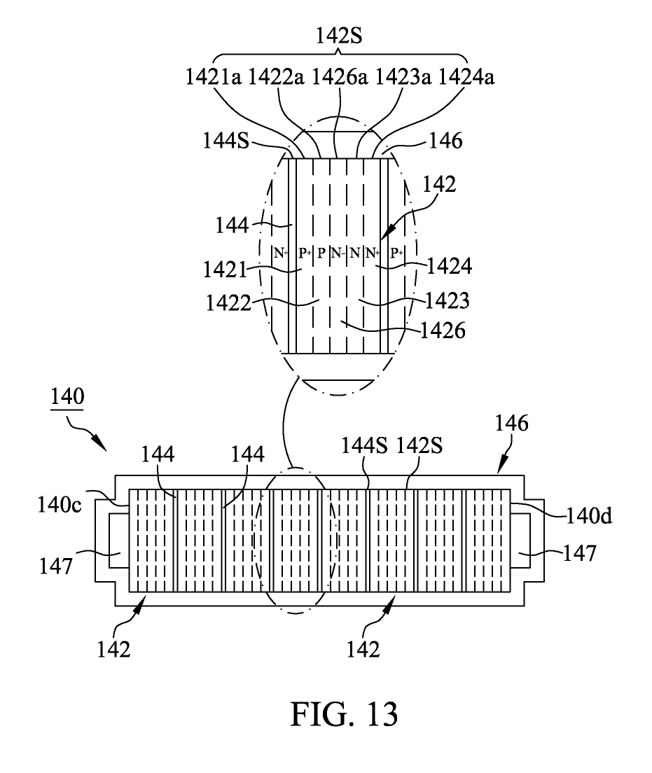

FIG. 13 illustrates a side view of a VMJ cell in accordance with some embodiments of the present disclosure.

Referring to FIG. 13, each of the PN junction substrates 142 can further include an N− type diffuse doping layer 1426. The N− type diffuse doping layer 1426 is disposed between and connected to the P type diffuse doping layer 1422 and the N type diffuse doping layer 1423. The N− type diffuse doping layer 1426 has an N− type end surface 1426a, and the N− type end surface 1426a is also covered with the passivation layer 146 to reduce the carrier recombination probability. In some embodiments, a doping concentration of the N− type diffuse doping layer 1426 is between about 10¹⁴ atom/cm³ and about 10¹⁸ atom/cm3.

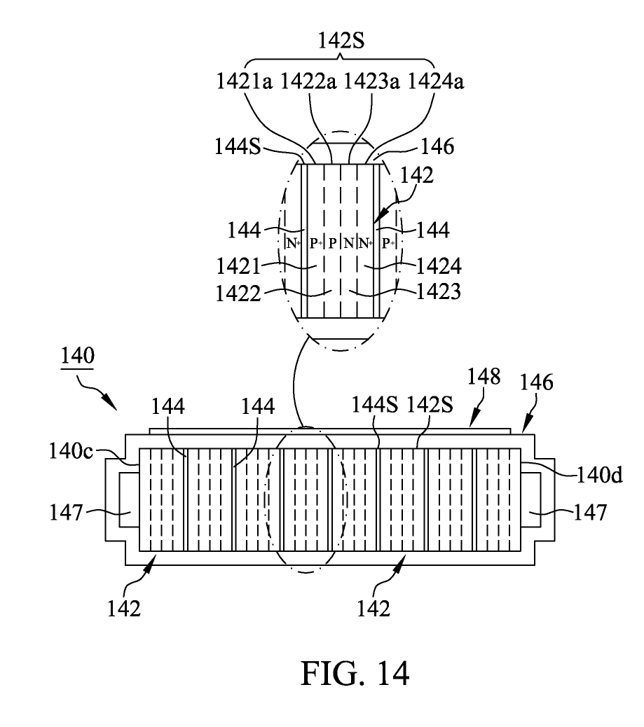

FIG. 14 illustrates a side view of a VMJ cell in accordance with some embodiments of the present disclosure.

Referring to FIG. 14, the VMJ cell 140 can further include an anti-reflective layer 148. The anti-reflective layer 148 covers part of the passivation s layer 146 to reduce surface reflections, and the anti-reflective layer 148 is penetrable to light. In some embodiments, the anti-reflective layer 148 is formed by a plasma enhanced chemical vapor deposition (PECVD) process. In some embodiments, the anti-reflective layer 148 is made of dielectric material selected from the group consisting of Si₃N₄ and SiO₂. In some embodiments, a thickness of the anti-reflective layer 148 is between about 10 nm and about 80 nm.

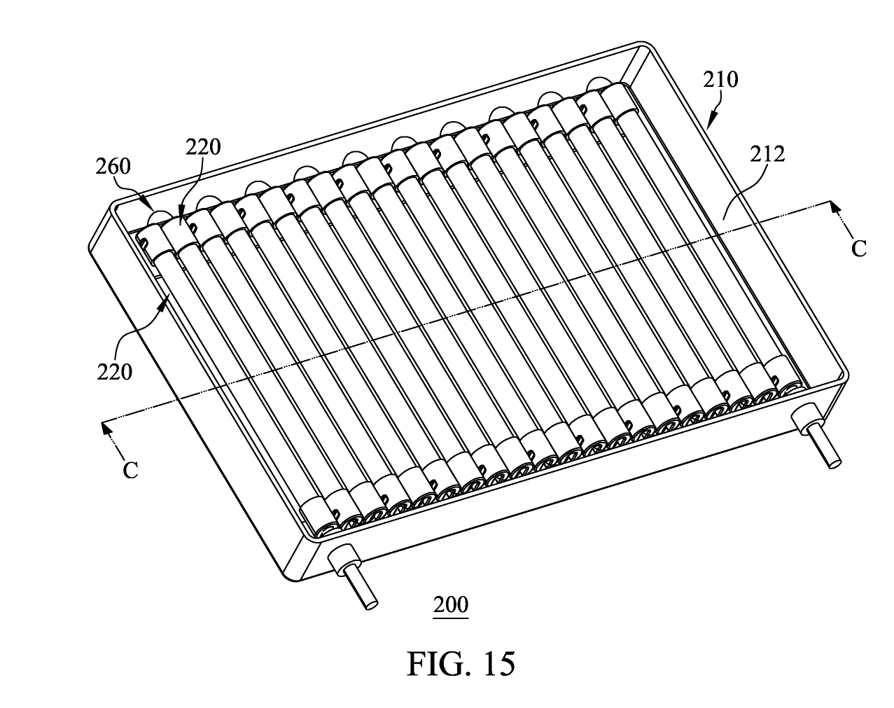

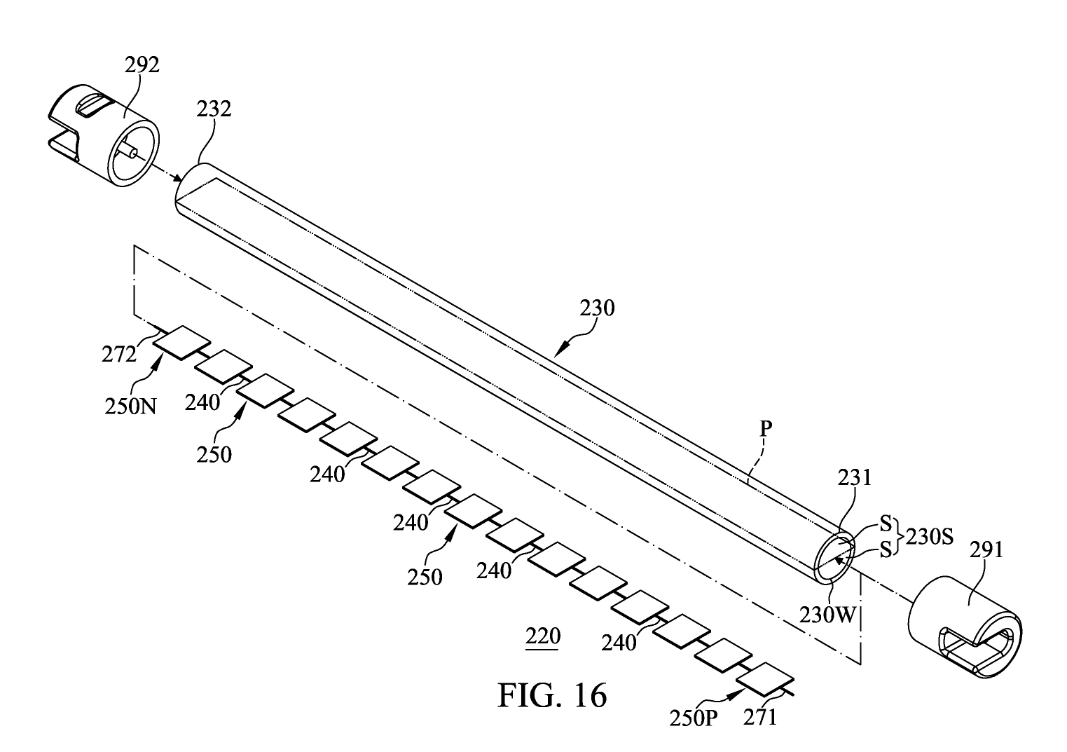

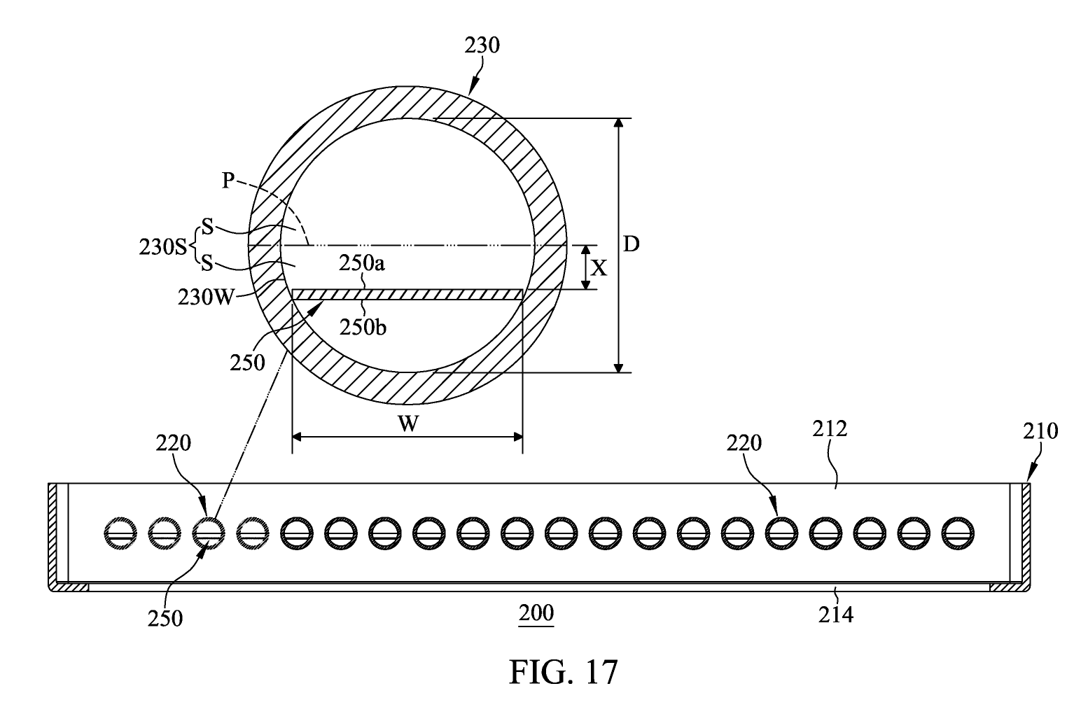

FIG. 15 illustrates a perspective view of a voltage source module in accordance with some embodiments of the present disclosure. FIG. 16 illustrates an exploded perspective view of a voltage source generator in accordance with some embodiments of the present disclosure. FIG. 17 illustrates a cross-sectional view along is line C-C of FIG. 15.

Referring to FIGS. 15, 16, and 17, a voltage source module 200 is designed to generate a kV-level voltage. The voltage source module 200 includes at least two voltage source generators 220 and at least one electrical connector 260. Each voltage source generator 220 includes a light-transmissive component 230 and a plurality of vertical multi-junction (VMJ) cells 250. The electrical connector 260 is connected to the voltage source generators 220. To generate the kV-level voltage, the voltage source generators 220 are connected in series through the electrical connector 260. In some embodiments, the voltage source generators 220 may be connected in parallel through the electrical connector 260.

The light-transmissive component 230 includes an inner space 230S, an inner wall 230W, a first end portion 231, and a second end portion 232. The second end portion 232 is opposite to the first end portion 231. The light-transmissive component 230 also has an internal diameter D and defines a bisecting plane P for dividing the inner space 230S into two spaces S.

The VMJ cells 250 are disposed within the inner space 230S of the light-transmissive component 230 to receive light and perform light-to-electricity conversion. Furthermore, the VMJ cells 250 are located at one of the two spaces S and are in contact with the inner wall 230W. In some embodiments, the VMJ cells 250 are substantially parallel to the bisecting plane P and there is a distance X between each VMJ cell 250 and the bisecting plane P. In some embodiments, a ratio of the distance X to the internal diameter D of the light-transmissive component 230 is between about 0.15 and about 0.45. In some embodiments, the VMJ cells 250 are connected in series, and each VMJ cell 250 has a width W smaller than the internal diameter D of the light-transmissive component 230.

Each voltage source generator 220 further includes a plurality of conducting components 240. Each conducting component 240 is disposed between and connected to two adjacent VMJ cells 250. The VMJ cells 250 are connected in series through the conducting components 240. In addition to the conducting component 240, a positive output component 271 and a negative output component 272 are provided to output the kV level voltage of each voltage source generator 220. In some embodiments, the VMJ cells 250 include a positive output VMJ cell 250P and a negative output VMJ cell 250N. The positive output component 271 is connected to the positive output VMJ cell 250P, and the negative output component 272 is connected to the negative output VMJ cell 250N. In some embodiments, the positive and negative output components 271, 272 are made of the same material as the conducting components 240.

To seal the light-transmissive component 230, a first end cap 291 and a second end cap 292 are provided. The first end cap 291 is disposed at the first end portion 231, and the second end cap 292 is disposed at the second end portion 232. In some embodiments, the positive output component 271 can be connected to the first end cap 291, and the negative output component 272 can be connected to the second end cap 292. Furthermore, the inner space 230S of the light-transmissive component 230 can be a vacuum space. In some embodiments, the inner space 230S of the light-transmissive component 230 can be filled with a gas.

To protect the voltage source module 200, a casing 210 is provided. In some embodiments, the voltage source generators 220 are disposed in the casing 210. In some embodiments, the voltage source generators 220 and the electrical connector 260 are disposed in the casing 210.

The casing 210 includes a first window 212 and a second window 214. The second window 214 is opposite to the first window 212, and the first and second windows 212, 214 expose the VMJ cells 250 of the voltage source generators 220. In some embodiments, each VMJ cell 250 includes a first light receiving surface 250a and a second light receiving surface 250b, and the second light receiving surface 250b is opposite to the first light receiving surface 250a. In some embodiments, the first light receiving surface 250a corresponds to the first window 212, and the second light receiving surface 250b corresponds to the second window 214.

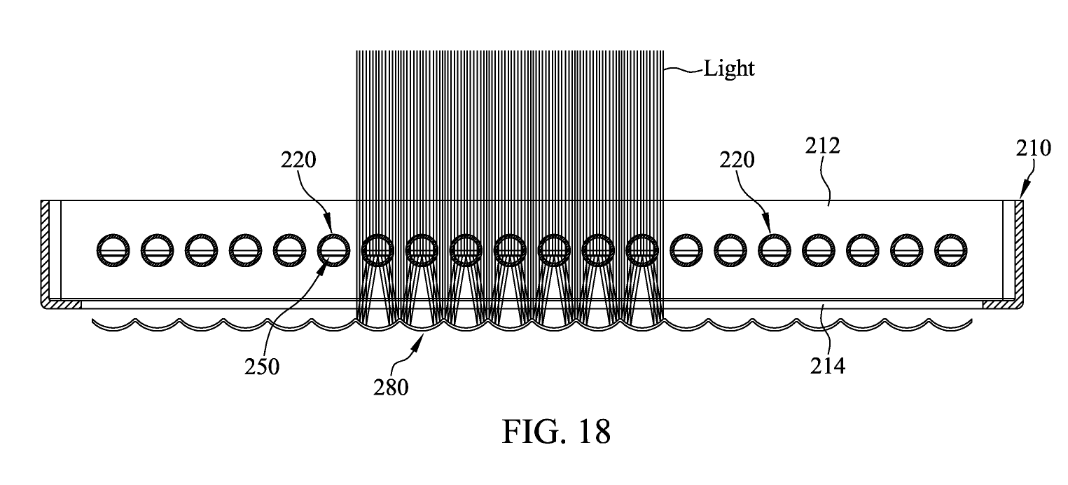

FIG. 18 illustrates a light reflector directing light onto VMJ cells in accordance with some embodiments of the present disclosure.

Referring to FIG. 18, some light illuminates the VMJ cells 250 through the first window 212 of the casing 210. Some light exits the casing 210 through the second window 214. Hence, the light exiting the casing 210 was wasted. To obtain a higher light-harvesting efficiency, a light reflector 280 is disposed outside the casing 210 for directing the light on the VMJ cells 250. In some embodiments, the light reflector 280 can be made up of angled flat or curved sections.

Table 1 presents the photovoltaic performance for voltage source generator with different tube number. Under one sun (0.09 W/cm²) illumination, the voltage source generator with one tube has an open-circuit voltage (V_{oc}) of 0.512 kV. Interestingly, increasing the tube number to 10 improved the V_{oc} to 5.03 kV.

TABLE 1

| Tube number | Cell number | Total cell area | Solar Energy | V_{oc} (kV) |
|---|---|---|---|---|
| 1 | 24 | 9.6 cm² | 0.09 W/cm² | 0.512 |
| 5 | 120 | 48 cm² | 0.09 W/cm² | 2.47 |
| 10 | 240 | 96 cm² | 0.09 W/cm² | 5.03 |

Moreover, the scope of the present application is not intended to be limited to the particular embodiments of the process, machine, manufacture, and composition of matter, means, methods and steps described in the specification. As those skilled in the art will readily appreciate form the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure.

Accordingly, the appended claims are intended to include within their scope such processes, machines, manufacture, and compositions of matter, means, methods or steps. In addition, each claim constitutes a separate embodiment, and the combination of various claims and embodiments are within the scope of the invention.

What is claimed is:

1. A voltage source generator, comprising:
a light-transmissive component including an inner space; and
s a plurality of vertical multi junction (VMJ) cells disposed within the inner space of the light-transmissive component to receive light and perform light-to-electricity conversion, wherein the VMJ cells are connected in series.

2. The voltage source generator of claim 1, wherein the light-transmissive component has an internal diameter, and each VMJ cell has a width smaller than the internal diameter of the light-transmissive component.

3. The voltage source generator of claim 1, wherein the light-transmissive component defines a bisecting plane for dividing the inner space into two spaces, and there is a distance between each VMJ cell and the bisecting plane.

4. The voltage source generator of claim 3, wherein the light-transmissive is component has an internal diameter, and each VMJ cell has a width smaller than the internal diameter of the light-transmissive component.

5. The voltage source generator of claim 4, wherein a ratio of the distance to the internal diameter of the light-transmissive component is between about 0.15 and about 0.45.

6. The voltage source generator of claim 3, wherein the VMJ cells are located at one of the two spaces.

7. The voltage source generator of claim 3, wherein the VMJ cells are substantially parallel to the bisecting plane.

8. The voltage source generator of claim 1, further comprising an index-matching material, wherein the inner space of the light-transmissive component is filled with the index-matching material.

9. The voltage source generator of claim 8, wherein the index-matching material has a refractive index between about 1.0 and about 2.0.

10. The voltage source generator of claim 8, wherein the index-matching material is an insulating material.

11. The voltage source generator of claim 8, wherein the index-matching material is selected from the group consisting of silica gel and epoxy resin.

12. The voltage source generator of claim 8, wherein the VMJ cells are encapsulated by the index-matching material.

13. The voltage source generator of claim 1, wherein the light-transmissive component includes an inner wall, and the VMJ cells are in contact with the inner wall.

14. The voltage source generator of claim 1, further comprising a light reflector disposed outside the light-transmissive component for directing light on the VMJ cells.

15. The voltage source generator of claim 14, wherein each VMJ cell includes a first light receiving surface and a second light receiving surface opposite to is the first light receiving surface, and the second light receiving surface faces the light reflector.

16. The voltage source generator of claim 15, wherein the light reflector directs the light toward the second light receiving surfaces of the VMJ cells.

17. The voltage source generator of claim 15, wherein the light reflector includes at least one concave surface corresponding to the second light receiving surfaces of the VMJ cells.

18. The voltage source generator of claim 14, wherein the light reflector can be made up of angled flat or curved sections.

19. The voltage source generator of claim 1, further comprising a plurality of conducting components, wherein each conducting component is disposed between and connected to two adjacent VMJ cells.

20. The voltage source generator of claim 19, wherein each conducting component includes a metal wire and a polyvinylidene fluoride (PVDF) coating, and the metal wire is encapsulated with the PVDF coating.

21. The voltage source generator of claim 20, wherein the metal wire is made of one selected from the group consisting of copper, nickel, tungsten, and molybdenum.

22. The voltage source generator of claim 19, further comprising a positive output component and a negative output component, wherein the VMJ cells include a positive output VMJ cell and a negative output VMJ cell, and the positive and negative output components are connected to the positive and negative output VMJ cells, respectively.

23. The voltage source generator of claim 19, further comprising a first end cap and a second end cap, wherein the light-transmissive component includes a first end portion and a second end portion opposite to the first end portion, and the first and second end caps are disposed at the first and second end portions, respectively.

24. The voltage source generator of claim 23, wherein the positive and is negative output components are connected to the first and second end caps, respectively.

25. The voltage source generator of claim 24, wherein the first end cap includes an electrical contact connected to the positive output component.

26. The voltage source generator of claim 24, wherein the second end cap includes an electrical contact connected to the negative output component.

27. The voltage source generator of claim 23, wherein the first or second end cap is flush to an outside surface of the light-transmissive component.

28. The voltage source generator of claim 1, wherein the inner space of the light-transmissive component is a vacuum space.

29. The voltage source generator of claim 1, further comprising an artificial light source disposed outside the light-transmissive component.

30. The voltage source generator of claim 29, wherein the artificial light source is selected from the group consisting of LED, incandescent lamp, fluorescent lamp, xenon arc, tungsten halogen, high intensity discharge lamps and combinations.

31. The voltage source generator of claim 1, wherein each VMJ cell includes a plurality of PN junction substrates and a plurality of electrode layers, wherein the PN junction substrates are spaced from each other, and each of the PN junction s substrates includes a P+ type diffuse doping layer, a P type diffuse doping layer, an N type diffuse doping layer and an N+ type diffuse doping layer, wherein the P+ type diffuse doping layer has a P+ type end surface; the P type diffuse doping layer is connected to the P+ type diffuse doping layer and has a P type end surface; the N type diffuse doping layer is connected to the P type diffuse doping layer and has an N type end surface; and the N+ type diffuse doping layer is connected to the N type diffuse doping layer and has an N+ type end surface, and each of the electrode layers is disposed between and connected to two adjacent PN junction substrates and has an exposing surface.

32. The voltage source generator of claim 31, wherein each VMJ cell is includes a passivation layer, and the passivation layer covers the P+ type end surfaces of the P+ type diffuse doping layers, the P type end surfaces of the P type diffuse doping layers, the N type end surfaces of the N type diffuse doping layers, the N+ type end surfaces of the N+ type diffuse doping layers and the exposing surfaces of the electrode layers.

33. The voltage source generator of claim 32, wherein each VMJ cell includes a first end surface, a second end surface opposite to the first end surface and two conducting electrodes separately disposed on the first and second end surfaces, and the first and second end surfaces are covered with the passivation layer.

34. The voltage source generator of claim 32, wherein each VMJ cell includes an anti-reflective layer covering part of the passivation layer, wherein the anti-reflective layer is penetrable to light.

35. A voltage source module, comprising:
at least two voltage source generators, each voltage source generator including a light-transmissive component and a plurality of vertical multi-junction (VMJ) cells, wherein the light-transmissive component includes an inner space; the VMJ cells are disposed within the inner space of the light-transmissive component to receive light and perform light-to-electricity conversion; and the VMJ cells are connected in series; and
at least one electrical connector connected to the voltage source generators.

36. The voltage source module of claim 35, wherein the voltage source generators are connected in series through the electrical connector.

37. The voltage source module of claim 35, further comprising a casing, wherein the voltage source generators are disposed in the casing.

38. The voltage source module of claim 37, wherein the casing includes a first window and a second window opposite to the first window, and the first and second windows expose the VMJ cells of the voltage source generators.

39. The voltage source module of claim 38, wherein each VMJ cell includes a first light receiving surface and a second light receiving surface opposite to the first light receiving surface, and the first and second light receiving surfaces correspond to the first window and the second window, respectively.

40. The voltage source module of claim 35, further comprising a light reflector disposed outside the casing for directing light on the VMJ cells.

41. The voltage source module of claim 35, wherein the light-transmissive component of each voltage source generator has an internal diameter, and each VMJ cell has a width smaller than the internal diameter of the light-transmissive component.

42. The voltage source module of claim 35, wherein the light-transmissive component of each voltage source generator defines a bisecting plane for dividing the inner space into two spaces, and there is a distance between each VMJ cell and the bisecting plane.

43. The voltage source module of claim 42, wherein the light-transmissive component of each voltage source generator has an internal diameter, and each VMJ cell has a width smaller than the internal diameter of the light-transmissive component.

44. The voltage source module of claim 43, wherein a ratio of the distance to the internal diameter of the light-transmissive component is between about 0.15 and about 0.45.

45. The voltage source module of claim 35, wherein the light-transmissive component of each voltage source generator includes an inner wall, and the VMJ cells are in contact with the inner wall.

46. The voltage source module of claim 35, wherein each voltage source generator further comprises a plurality of conducting components, and each conducting component is disposed between and connected to two adjacent VMJ cells.

47. The voltage source module of claim 46, wherein each voltage source generator further comprises a positive output component and a negative output component; the VMJ cells includes a positive output VMJ cell and a negative output VMJ cell; and the positive and negative output components are connected to the positive and negative output VMJ cells, respectively.
